(19) United States
(12) Patent Application Publication
(10) Pub. No.: US 2001/0011765 A1
(43) Pub. Date: Aug. 9, 2001

(54) Switch recognition system

(76) Inventor: Fermin Pena Arruti, Gipuzkoa (ES)

Correspondence Address: Iandiorio & Teska, 260 Bear Hill Road, Waltham, MA, 02451-1018, US

(21) Appl. No.: 09/775,899

(22) Filed: Feb. 2, 2001

(30) Foreign Application Priority Data
Feb. 4, 2000 (GB) 0002534.6

(51) Int. Cl. H01L 23/02

(52) U.S. Cl. 257/679

(57) ABSTRACT

A switch for an energy management system. The switch is of the general type comprising a housing 1 and a key card 11, the housing having in opening 4 for insertion of the key card and a switch means triggered by the presence of the key card. The switch means controls access to at least one energy consuming service. The housing includes at least one magnetically linked reading switch that recognizes magnetically responsive portions on the key card to prevent it being replaced by an imitation card.

### FIELD OF THE INVENTION

This invention relates to switches and control or authorisation of switching.

### BACKGROUND TO THE INVENTION

In many hotels it is desired to control lighting and air conditioning to prevent energy consumption when rooms are unoccupied. One system that has been developed for this is replacement of the usual finger operated up/down or rocker switches at room entrances with an assembly having a slotted switch housing into which the door key card is inserted in order to operate the switching mechanism. Such switches are mechanically operated by the key card and require the key card to remain in the slot in order to maintain the switch in the ‘on’ position. Thus when the occupant leaves the room, and therefore takes out the key card in order to be able to regain entry, the lights, air conditioning and other electrical devices attached to the switch circuit are switched off.

The switches of this kind operate by virtue of the mechanical action of the key card in the slot, for example by pushing a spring biased member. Therefore it is possible to operate the switches by insertion of any other card or suitably sized member and leave the electrical devices running while the room is unoccupied. This is particularly undesirable for cost and environmental reasons.

The present invention is directed towards preventing improper activation of key card controlled switches.

### SUMMARY OF THE INVENTION

According to the invention there is provided a switch assembly of the type comprising a housing and an actuating member such as a key card, the housing having an opening for receipt and retention of the key card and switch means responsive to the presence of the key card, the switch means controlling access to at least one electrical energy consuming service. The assembly includes at least one magnetically linked reading switch and the key card has at least one magnetically responsive portion located for cooperative alignment with the reading switch, the reading switch operating to permit access to said at least one electrical service only when there is a predetermined alignment match between the at least one key card portion and the reading switch. The magnetic linkage may be an electromagnetic linkage

### BRIEF DESCRIPTION OF THE DRAWINGS

The invention is now described by way of example with reference to the accompanying drawings in which:

FIG. 1 illustrates in expanded schematic perspective view a housing for a switch of the general type requiring key card operation;

FIG. 2 is a schematic end view of a housing modified according to an embodiment of the invention;

FIG. 3 is a schematic plan view of components inside a front cover of a switch housing according to an embodiment of the invention;

FIG. 4 is a schematic plan view of components inside a back plate of a switch housing according to an embodiment of the invention;

FIG. 5 illustrates schematically, operational parts of an embodiment of a switch according to the invention with the switch in the off configuration;

FIG. 6 illustrates, schematically, the embodiment of FIG. 1 with the switch in the on configuration; and

FIG. 7 is a schematic illustration of a switch circuit for use in an embodiment of the invention.

### DETAILED DESCRIPTION OF PREFERRED EMBODIMENTS

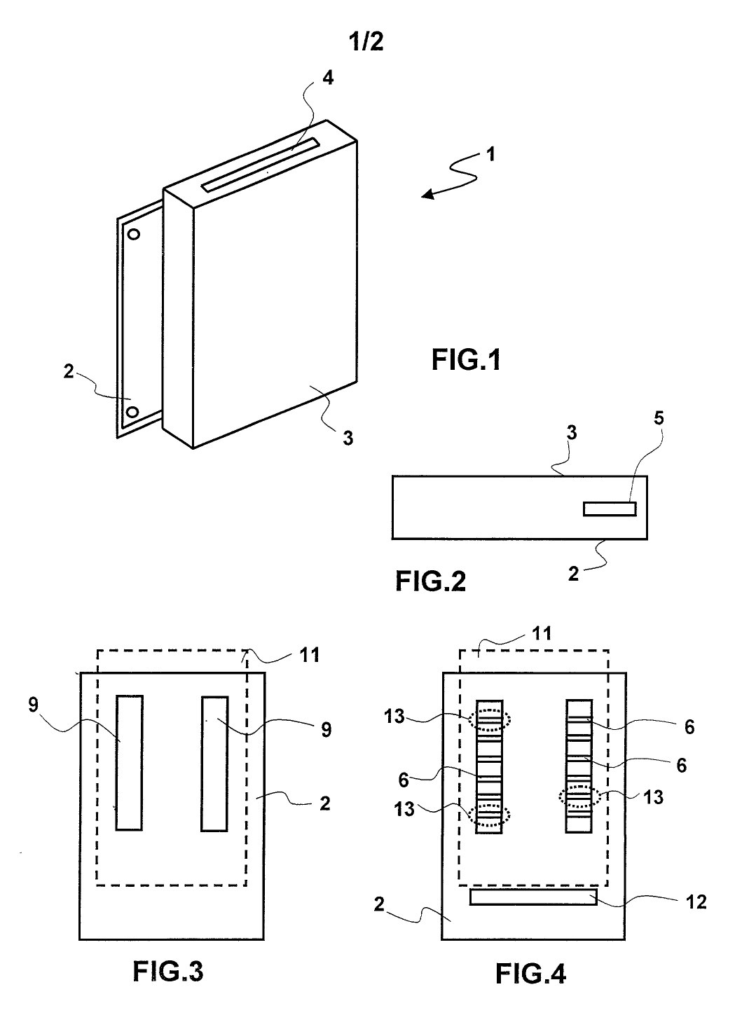

Referring to the drawings, FIG. 1 shows a housing for a switch of the general type requiring key card operation. The housing comprises a back plate 2 that is suitable for fixing to a wall and carrying a circuit make/break switch. A front cover 3 secures over the back plate and has a slot 4 through which a key card may be inserted to engage mechanically with the circuit make/break mechanisms

The present invention incorporates the general features of the prior art switch of this type in either a similar or modified form, described in connection with FIGS. 2 to 6. In the present invention the key card can not be substituted by another card or object of similar configuration because the switch has a recognition system that is specific, for example, to residents' key cards of a particular hotel. The combination with the access key to a room or main entrance is particularly useful for limiting ‘ON’ periods to those of occupancy. However other types of key or actuation members other than keys or card formats are possible.

In the preferred embodiment the recognition system comprises one or more magnetically operated reed switches in the housing and a magnetically responsive material in the key card. It is possible for the circuit switching to be controlled by the one or more reed switches, but in the preferred embodiment the mechanically actuated switch is also present, both the mechanically actuated switch and the reed switch (or switches) having to be triggered in order to engage the switch assembly into the ‘on’ setting for the attached circuit.

FIG. 2 is a view from below of the switch housing showing a small slot 5. Other features are not shown. The significance of slot 5 is that in the preferred embodiment with both magnetic reed switching and mechanical switching, slot 5 permits access to an override mechanism for disengaging the reed switching so that the switch assembly will operate on the mechanical switch only. The override mechanism is intended to be operated if there are faults in the magnetic reed switching, or could be used for seasonal adjustments.

More detail of the reed switching is now described with reference to FIGS. 3 to 7.

Referring first to FIGS. 5 and 6, a single reed switch has a magnetically responsive contact 7 which moves to make or break a ‘disable’ circuit 8 to which the switch is connected A magnet 9 is disposed in line with the contact 7 and, as shown in FIG. 5, the magnetic flux extends from the magnet to the contact 7 and attracts the contact to the magnet causing it to abut a stop 10 and complete the disable circuit. Completion of this circuit 8 is arranged to disable the main circuits connected to the switching assembly

An example of a suitable disable circuit is shown in FIG. 7. The control on disable circuit extends between points X-X, between which, in this example four switches are interposed The control circuit enables the operation of the main circuit when the switches provide an open circuit. Switches 20 and 21 are reed switches, which are controlled by the key card. Switch 22 is the mechanical switch, switch 23 is the mechanical override which can be set to open, thereby bypassing the function of the reed switches, so that the circuit responds solely to the mechanical switch.

A key card 11 is insertable between the reed switch and magnet, as shown in FIG. 6. The key card has a magnetically responsive material aligned in the path of the magnetic flux, and therefore linkage with the contact 7 is cut off. Spring action of the reed disconnects the contact 7 from stop 10, thereby breaking circuit 8 and breaking the associated main circuit disable. As indicated earlier, this mechanism can be used as the main control, but it is preferred as a supplementary control to a second mechanical switch mechanism.

FIGS. 5 and 6 are simplistic and show only a single reed switch. Preferably several reed switches are present and the key card provided with several magnetically active portions for alignment with respective reed switches. By placing reed switches only in a particular combination of locations or by connecting particular ones of the reed switches in the disable circuit, and providing the key card with a corresponding pattern, it is possible to provide a large range of different combinations so that only a correctly coded key card will break the disable circuit.

In simple systems all the rooms and residents' key cards for a particular hotel will have a single code pattern. More complex arrangements are possible where reed switches may connect to different ones or combinations of disable circuits, for example allowing or restricting access to air conditioning with differently coded key cards. To prevent abuse by insertion of a correctly sized magnetisable member or a master key with magnetisable material in every location, the correct pattern of both open and closed reed switches may be utilised as the requirement to break one or more disable circuits. In such an instance opening a reed switch that should not be set to open would maintain the disable.

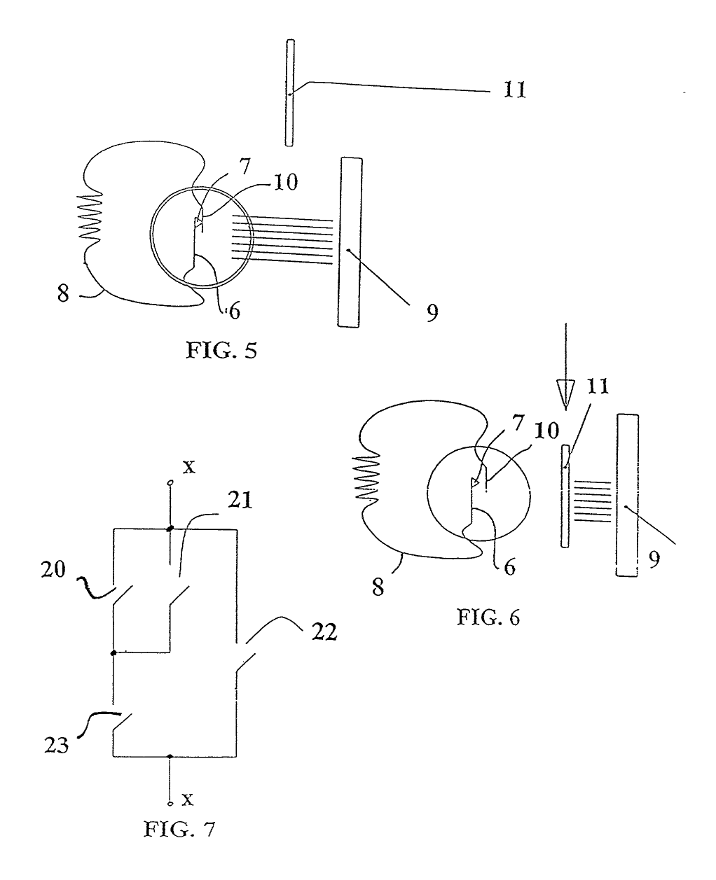

Referring now to FIGS. 3 and 4, a suitable layout for the reed switch mechanism is illustrated in the front cover and back plate. The front cover 3 contains magnets 9. As illustrated in FIG. 3, two magnets 9 are shown but one, or more than two may be used.

The back plate 2 has two columns for the positioning of reed switches 6 corresponding in layout to the magnet pattern. As shown this is two vertical columns but other arrangements and orientations are possible for arrays of switches and corresponding magnets A mechanically biased switch 12 is also present at the base end of the columns where it is mechanically engaged by the key card 11. A convenient number of reed switches to accommodate in each column is six. The magnets 9 may be removable as part of the coding option or for simpler systems. For coding purposes not all the reed switches need to be connected (or even present) in the enable/disable circuit, only those which are to be active. In FIG. 4 the active switches are aligned with dotted rings 13 which represent the corresponding aligned magnetically responsive portions of the key card 11, also shown in dotted outline in the Figure.

It will be appreciated that different configurations of keys or other actuating member, not just cards, could be utilised.

1. A switch assembly of the type comprising a housing and an actuating member, the housing having an opening for receipt and retention of the actuating member and switch means responsive to the presence of the actuating member, the switch means controlling access to at least one electrical energy consuming service, the assembly includes at least one magnetically linked reading switch and the actuating member has at least one magnetically responsive portion located for cooperative alignment with the reading switch, the reading switch operating to permit access to said at least one electrical service only when there is a predetermined alignment match between the at least one magnetically responsive portion and the reading switch

2. A switch assembly according to claim 1 in which the magnetically linked reading switch comprises a reed switch and a magnet and the magnetically responsive portion of the actuating member is arranged to be disposed in a gap between the reed switch and magnet

3. A switch assembly according to claim 1 comprising an array of magnetically linked reading switches, selected ones of which define a code pattern that corresponds to a code pattern of magnetically responsive portions in the actuating member

4. A switch assembly according to claim 1 in which the at least one magnetically linked reading switch constitutes the switch means controlling access to the at least one electrical energy consuming service

5. A switch assembly according to claim 1 in which the at least one magnetically linked reading switch is a separate service disabling switch from the switch means controlling access to the at least one electrical energy consuming service

6. A switch assembly according to claim 5 in which said switch means also comprises a mechanical switch activated by insertion of the actuating member

7. A switch assembly according to claim 5 further comprising means to override the magnetically linked reading switch

8. A switch assembly according to claim 1 in which the actuating member comprises a key card
